(19) United States
(12) Patent Application Publication
(10) Pub. No.: US 2015/0084637 A1
(43) Pub. Date: Mar. 26, 2015

(54) ASSEMBLY AND METHOD FOR EVALUATING THE STATE OF AN ELECTRONIC UNIT USED FOR ILLUMINATION PURPOSES

(71) Applicant: ZUMTOBEL LIGHTING GMBH, Dornbirn (AT)

(72) Inventor: Michael Boehnel, Dornbirn (AT)

(21) Appl. No.: 14/396,774

(22) PCT Filed: Apr. 26, 2013
(86) PCT No.: PCT/EP2013/058722

§ 371 Date: Oct. 24, 2014

(30) Foreign Application Priority Data
Apr. 26, 2012 (SE) 10 2012 206 891.0

(51) Int. Cl. H05B 37/03; G01R 31/44

(52) U.S. Cl. CPC H05B 37/03; G01R 31/44
USPC 324/414

(57) ABSTRACT

An assembly for evaluating the state of an electronic unit used for illumination purposes which is designed to detect a plurality of physical parameters that represent the current state of the electronic unit, to compare the detected physical parameters according to possibly mathematical evaluation or analysis alone or in combination with predefined reference values or reference spaces (I, II), and to create information describing the state of the electronic unit to be evaluated on the basis of the comparisons.

The present invention relates to an assembly with the aid of which the state of an electronic unit used for illumination purposes can be evaluated. Furthermore, the present invention relates to a corresponding method. In this context, a particularly preferred exemplary application for the present invention is represented by the evaluation of the state of LED-based light sources, especially of LED modules or OLED modules.

Due to the development in recent years, LED light sources are also used increasingly for illumination purposes. If such light sources were not adequate with regard to their light intensity to provide for a satisfactory illumination of an area to be illuminated, conventional light sources such as, for example fluorescent lamps or the like, can now be replaced by LED-based light sources in almost all fields. In this context, such LED light sources often also offer the advantage that they are more easily variable with regard to their light emission, for example dimmable. Multi-colored LED light sources now also provide the option of being able to adjust the color or color temperature of the light emitted almost arbitrarily.

A further advantage of LED light sources consists in that they have a relatively long life which applies at least to the luminous flux emitted by the light source or achievable via the light source. In fact, however, such light sources also naturally have a limited life which depends on the manner of operating the light source and the operating state and the activation of the light source. Due to the ever increasing use of LED-based lamps, it can be expected that in future a change or an exchange of defective LED light sources or an exchange of the complete lamp will also be required on site.

Since, in comparison with traditional light sources such as incandescent lamps or fluorescent lamps, an exchange of defective units, as a rule, can only be performed by technical personnel in the case of LED light sources, it would be desirable to be able to recognize an impending final failure of such a light source as early as possible. Hitherto, however, relatively few options exist in this respect, i.e. relatively small faults or defects in the operation of the LED light source are only noticed at a time at which the light source fails completely. Slow changes of parameters which can lead to damage and thus to a total failure of the light source at a later time cannot be recognized prematurely, however, until now. This is problematic in the case of such LED light sources since—as already mentioned—an exchange of a defective light source cannot be performed by the end user himself, as a rule, but only by technical personnel and accordingly a relatively long time will pass possibly until the final exchange.

The present invention is, therefore, based on the object of specifying a novel solution which enables the state of a corresponding LED-based light source to be evaluated in order to recognize possibly impending malfunctions or problems which can lead to a total failure of the light source as early as possible.

The object is achieved by an assembly for evaluating the state of an electronic unit used for illumination purposes, having the features of claim 1, and by a method as claimed in claim 13. Advantageous developments of the invention are the subject matter of the dependent claims.

It should be mentioned first that, according to the problem described above, a particularly preferred exemplary application of the present invention consists in evaluating the state of an LED light source. However, the concept according to the invention is not restricted to this special application but can be used whenever electronic units are to be evaluated which are used for illumination purposes. These can be a light-emitting means, especially an LED module, an OLED module, a halogen lamp, a gas discharge lamp or a fluorescent lamp. In addition, however, it would also be possible to evaluate the state of other electronic units, for example of operating devices for operating a light-emitting means or of an operating device for driving lamps or operating devices for light-emitting means according to the concept according to the invention.

This inventive concept is based on the idea of performing as extensive as possible an evaluation of the state of the electronic unit to be evaluated as part of the monitoring of a state. According to the invention, a plurality of physical parameters or raw data representing the current state of the electronic unit are detected in a first step, these detected raw data then being compared, possibly after corresponding mathematical processing or analysis alone or in combination with predetermined reference values or reference spaces in a further step. On the basis of these comparisons, information describing the state of the electronic unit to be evaluated is finally created.

As part of this state monitoring and evaluation according to the invention, it is possible to obtain detailed information with regard to faulty states which, although they possibly do not have a direct effect on the operability of the electronic unit to be evaluated, may lead to a serious fault within a foreseeable period of time. In the exemplary application described initially, of monitoring LED light sources, this means that it is possible to determine even before a final failure of the light source that it is faulty. It is then possible, as part of cyclic maintenance work, to replace a correspondingly faulty light source before it fails completely. It is obvious that this leads to distinct advantages in comparison with a procedure in which maintenance measures are initiated only after the final failure of the light source.

The information finally created according to the invention, which describes the state of the electronic unit to be evaluated, is provided—as already mentioned—on the basis of the comparison between the physical parameters detected and possibly processed, and predetermined reference values or reference spaces. These results of the comparison can then be weighted to a different extent according to an advantageous development of the invention since deviations from the reference values or reference spaces can have a different degree of effect on the state of the electronic unit to be evaluated with respect to different parameters. Furthermore, the degree of deviation can also be taken into consideration, the reference values or reference spaces being graded preferably at least partially.

These reference values or reference spaces which are the starting base of evaluating the state of an electronic unit to be evaluated are preferably specified at the beginning. In particular, these values or spaces can be specified on the basis of measurement results which were obtained during the production or immediately after production of the electronic unit to be evaluated. These spaces or values are thus based on the initial state of the electronic unit in which, as a rule, the ideal operating state of the unit is achieved. In this context, it can be provided that the reference values or reference spaces remain permanently unchanged. On the other hand, the ideal state of an electronic unit to be evaluated can definitely change over its life which is attributable, for example, to aging phenomena or the like. According to a particularly preferred exemplary embodiment, the assembly can be designed correspondingly to modify the reference values or reference spaces used for comparing independently.

The physical parameters used for evaluating the state of the electronic unit are obtained as part of measurements, the assembly according to the invention either itself having corresponding means for this purpose or being designed to be connected to corresponding sensors or measuring devices. The detected physical parameters can be, in particular, temperature, voltage, current, luminous flux, brightness, color, frequency and/or time values but also spectral components such as, for example, amplitude values in particular frequencies. This depends especially also on the type of the electronic unit to be evaluated. In this context, the assembly for the evaluation can represent a separate component or can be an integral component of the unit to be evaluated.

In the text which follows, the invention will be explained in greater detail by means of the attached drawing, in which:

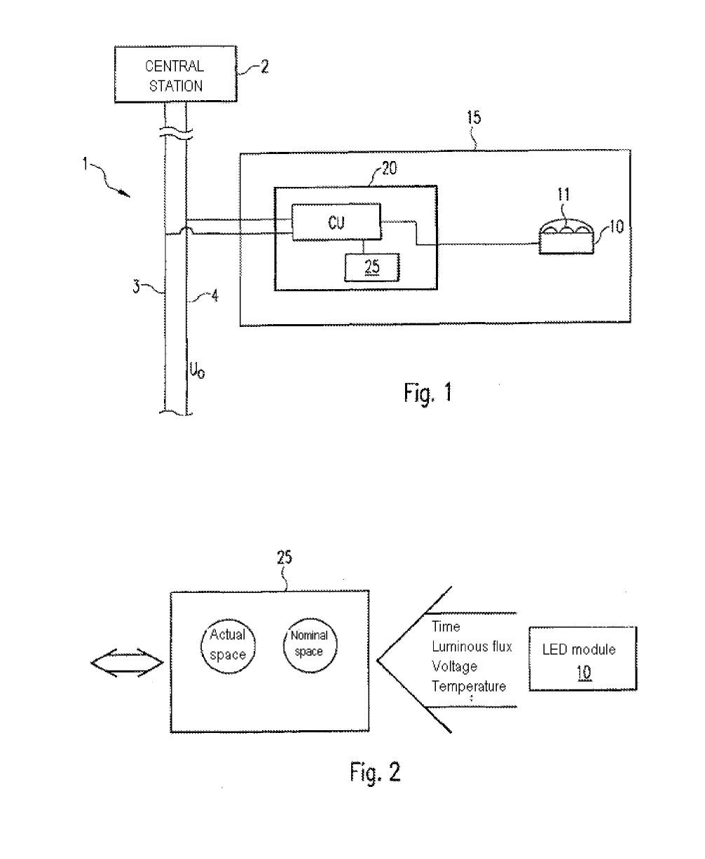

FIG. 1 shows diagrammatically an exemplary application of the present invention in which the state of an LED light source is evaluated;

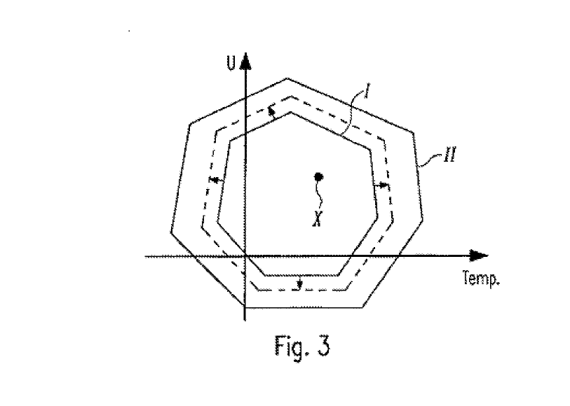

FIG. 2 shows diagrammatically the collaboration of the assembly according to the invention with the LED light source to be evaluated, and

FIG. 3 shows an example of the creation of a comparison result flowing into the final evaluation of the state.

In the exemplary application of the present invention, shown in FIG. 1, the state of an LED-based light source is to be monitored and evaluated. This light source provided with the reference symbol 10 is formed by an LED module which has, for example, a number of LEDs 11 of different color. In this arrangement, a light adjustable in its overall color and color temperature can be obtained here by correspondingly activating the brightness of the differently colored LEDs 11 of the module 10.

In the present case, the LED module 10 is a component of a lamp 15 which, in turn, is a component of a larger illumination system 1. This has a central control device 2 which is connected to lamps 15 of the system 1 via a bus line 3. For this purpose, the lamp 15 has internally an operating device 20 which, on the one hand, is responsible for communication with the central control unit 2 via the bus system 3 and, on the other hand, activates the LED module 10. In particular, the operating device 20 can be designed in a familiar manner to convert a supply voltage U₀ provided via the general power supply 4 into a suitable operating voltage for operating the LED module 10 or its individual LEDs 11, respectively, on the basis of existing control commands.

As mentioned initially, the problem with corresponding LED-based light sources is that faulty operating states could not be detected reliably hitherto if they did not have a direct effect on the operability of the LED module 10. Although a total failure of the light source could naturally be detected, it was not possible to identify an impending failure in advance and correspondingly to take corresponding maintenance measures in time, for example an exchange of the LED module 10.

It is intended to avoid this problem now by means of the solution according to the invention. For this purpose, it is provided that a unit for evaluating the state of the LED module 10 is used. This monitoring or evaluation unit 25 is an integral component of the operating device 20 in the present example but it could also be arranged separately therefrom in the lamp 15 or as a completely independent unit, that is to say constructed separately from the operating device 20 and the lamp 15. It is the object of this unit 25 to evaluate the state of the LED module 10 continuously or at regular intervals and to generate from this corresponding information. This can then be conveyed from the operating device 20 to the central control unit 2, if necessary. If, for example, the unit 25 determines that a failure of the LED module 10 is to be expected soon, this information is forwarded to the central station 2 which can initiate corresponding maintenance measures. As an alternative to this report via the operating device 20, it would also be conceivable, however, that corresponding information is transmitted by other means. This could take place, for example, also wirelessly or optically, the unit 25 then being equipped with corresponding communication means.

In the text which follows, the general interaction between the evaluation unit 25 and the LED module 10 and the operation of the unit 25 according to the invention is to be explained in greater detail by means of FIG. 2. Essentially, the state of the LED module 10 is evaluated in a number of successive steps. In this context, raw data are collected in a first step for the later evaluation of the state of the LED module 10. In particular, this is done by detecting the physical parameters of the LED module 10 by means of the unit 25 which is illustrated diagrammatically by the corresponding arrow. For this purpose, the unit 25 can have corresponding measuring devices or sensors or at least be connected to corresponding sensors in order to detect the parameters. These can be the most varied parameters such as, for example, time, luminous flux, voltage, temperature etc., different parameters being monitored depending on the type of electronic unit to be evaluated. These physical parameters can be detected continuously or regularly at certain time intervals. Detecting the parameters in each case on activation of the LED light source would also be conceivable.

As already mentioned, the physical parameters obtained in this manner in the first step represent the raw data for the later evaluation of the state of the LED module 10. In a successive second step, features are generated from the detected raw data by mathematical calculation, conversion or analysis. However, it is also conceivable that the raw data themselves represent features without further processing. In a third step, features are then combined to form a feature vector which represents the interaction or the mutual dependence of the physical values. It is also conceivable that a single feature forms a feature vector. In consequence, feature vectors can be one- two- three- but also higher-dimensional. In a successive fourth step, this feature vector is then compared with a predetermined reference space and leads to a corresponding comparison result. The respective reference spaces can also be one-, two-, three- or higher-dimensional, suitably in each case in accordance with the dimension of the feature vector to be compared.

An example of a comparison of the interaction of two physical measurement values with a predetermined reference space is shown in FIG. 3, the interaction between a voltage U present at the LED module 10 with the resultant temperature Temp at the LED module 10 being checked. As part of the measurement performed before, the temperature present at the LED module 10, on the one hand, and the present voltage, on the other hand, is determined. In the example shown, this results in a two-dimensional reference space with a point corresponding to the measurement result or feature vector X, respectively, it being checked whether this point X lies within a predetermined permissible reference space or outside thereof. In the exemplary embodiment shown, this reference space is identified by the area delimited by the curve I.

If thus the value X determined by the measurements is within this area I, the characteristic of the LED module 10 to be evaluated is within a permissible area as part of this comparison. With respect to this feature vector, there is thus no deviation from the standard state. If, in contrast, the feature vector were to lie outside the permissible area I, this would indicate a fault state, at least for this feature vector, which may lead to an impairment of the operability of the module overall.

As part of this fourth step, characteristics of the LED module represented by a feature vector are thus checked and it is determined whether one or more parameters characterizing these characteristics lie within or outside a permissible area. In this context, the example in FIG. 3, which shows the relationship between voltage and temperature, represents a conceivable feature vector X to be evaluated since two or generally a plurality of characteristics are considered here in combination. During the evaluation of an LED module, the relationship between current and voltage can also be evaluated additionally as a further feature vector in order to determine whether there is any damage to be attributable to electrostatic discharge (ESD). It would also be conceivable to evaluate the interaction between power, temperature at the module and ambient temperature which enables possible damage at the means for removing the heat produced during the LED operation to be detected. Apart from the feature vectors just described, other characteristics or features can also be considered in isolation, however.

The aforementioned examples illustrate that the respective comparisons with reference spaces are performed not only for individual physical parameters in isolation, that is to say in one-dimensional space, but that a comparison in higher-dimensional spaces, particularly in two-dimensional or three-dimensional spaces can also take place. Each comparison of a feature vector with an associated reference space then leads to a corresponding comparison result (e.g. in the form of a code number) which supplies information on the corresponding characteristic or the corresponding combination of characteristics of the LED module.

Furthermore, it must be pointed out that it is not necessarily the measured physical parameters or raw data which must be utilized when performing the comparison. Thus, these measurements can also be first mathematically evaluated or analyzed and the resultant findings can flow into the comparison. For example, it is frequently sensible in a time-dependent measurement of a parameter to subject the corresponding result to a Fourier analysis and to allow the frequency characteristics, obtained therefrom, of the parameter to flow into the comparison.

A further development with regard to the comparisons described before can also consist in that it is not only that a statement is made on whether the measurement value obtained is within or outside a permissible area but additionally it is also taken into consideration how great the distance from the permissible reference space is if the feature vector is outside it. It would also be conceivable to specify the ideal state of the device as a point in a reference space and to allow the determination of the deviation of the feature vector from the predetermined nominal value to flow into the comparison result. For example, graded reference spaces can also be utilized for obtaining a more detailed statement about the corresponding feature or the combination of features of the LED module, a maximum permissible area (shown in FIG. 3 by the curve II) then specifying within which range of values the corresponding feature vector should be located in every case. If, in contrast, the value is outside this maximum permissible area II, a corresponding error is definitely present in this characteristic.

The comparison or reference spaces are specified preferably at the beginning and represent the ideal state of the LED module. The choice of as low as possible a dimension for the reference spaces in the phase of forming the model is particularly appropriate in this case. These reference spaces can be defined, for example as part of the production of the module or immediately after its production, the information required for this being obtained as part of measurements. A development of the concept would then be possible to the extent that the reference space is adapted in the course of the operating time of the LED module as is illustrated by the curve shown dashed in FIG. 3. This may be appropriate, for example, for taking into consideration aging phenomena resulting in the course of operation which, however, do not yet indicate a defect of the module. In this context, it can be provided, for example, that a corresponding adaptation of the permissible reference space only takes place during a particular period of time, for example during the first 100 operating hours of the LED module.

A further continuation of the concept of adaptive reference space definition consists in that the reference space extends independently under certain circumstances. If, for example, a feature vector to be compared is outside the predetermined reference space, the evaluation unit 25 detects independently whether an extension by this range is permissible and conducts a recalculation and thus redetermination of the reference space for future use.

On the basis of these comparisons or the code numbers determined as part of the comparison, state information with regard to the state of the LED module is finally created in a fifth step. For this purpose, the monitoring unit 25 has internally a corresponding evaluation unit which combines the comparison results, possibly under the influence of different weighting of the former, with one another, determines a single state code and evaluates the state by means of this state code. Naturally, a multiplicity of comparison results in which the corresponding values are outside the permissible reference space will then lead to a negative evaluation of the state of the LED module. However, the fact that a single comparison has a negative result does not necessarily indicate already a fault of the module. It is important that the interaction of the various comparison results flows into the final evaluation of the state, wherein the comparison results can be weighted to a different degree. During this process, however, no complex evaluation of the comparison results is performed as part of elaborate algorithms which are based, e.g. on a physical model of the device to be evaluated, but there is a simple numeric evaluation with regard to checking the extent to which the comparison results or the code numbers determined and the state information determined from this which indicate an error probability indicate a particular state of the device.

State information can be provided, in particular, by percentage reliability information, in the specification of expected life or by absolute information on the state such as, for example, “OK” and “NOT OK”.

Depending on the result of this final evaluation, it can then be provided that the unit 25 provides a corresponding report to the operating device 20 or the central control unit 2. As already mentioned, the unit 25 has for this purpose corresponding means for communication. After obtaining information which indicates an impending failure of the module, corresponding measures can then be initiated, particularly an exchange of the module.

By means of the procedure according to the invention, clearly detailed information with regard to operating state of the LED module can thus be obtained. In this manner, it can be prevented that a corresponding module fails surprisingly and unnecessarily much time elapses before corresponding maintenance work. This is of advantage particularly in the case of lamps, the permanently reliable operation of which is required, for example in the case of emergency lamps or rescue signal lamps.

However, the concept described above can be used not only in the evaluation of the state of LED light sources but is applicable to the most varied electronic components in a variety of manners. Thus, the operating state of the lamp operating device 20 could also be monitored in a comparable manner. It is also possible to evaluate all types of light sources in this manner, particular emphasis being placed on OLED-based light sources since these provide the same problems as LED light sources, that is to say hitherto errors in the operating state of such light sources could only be detected after their final failure. Finally, it would also be possible to test the operability of corresponding operating devices or control devices with the aid of which lamps or lamp-operated devices are activated, in the manner according to the invention.

1. An assembly for evaluating the state of an electronic unit used for illumination purposes, wherein the assembly is designed
a) to detect a plurality of physical parameters that represent the current state of the electronic unit,
b) to compare the detected physical parameters after possibly mathematical evaluation or analysis alone or in combination with predetermined reference values or reference spaces, and
c) to create information describing the state of the electronic unit to be evaluated on the basis of the comparisons.

2. The assembly as claimed in claim 1, wherein during the creation of the state information, the comparison results are weighted to a different extent.

3. The assembly as claimed in claim 1, wherein the reference values or reference spaces (I, II) used for comparing are at least partially graded.

4. The assembly as claimed in claim 1, wherein the reference values or reference spaces used for comparing are specified during the production or immediately after production of the electronic unit to be evaluated, preferably on the basis of measurement results.

5. The assembly as claimed in claim 1, wherein the reference values or reference spaces (I, II) used for comparing remain permanently unchanged.

6. The assembly as claimed in claim 1, wherein the assembly is designed to modify the reference values or reference spaces (I, II) used for comparing independently, wherein the modifying of the reference values or reference spaces (I, II) takes place preferably within a predetermined period of time after the electronic unit to be evaluated has been taken into operation.

7. The assembly as claimed in claim 1, wherein it has means for measuring the physical parameters.

8. The assembly as claimed in claim 1 wherein it is designed to be connected to sensors or measuring devices for detecting the physical parameters.

9. The assembly as claimed in claim 1 wherein, the detected physical parameters are, in particular, temperature, voltage, current, luminous flux, brightness, color, frequency, time values and/or spectral components.

10. The assembly as claimed in claim 1 wherein it has an interface for reading out data.

11. The assembly as claimed in claim 1 wherein it is an integral component of the electronic unit to be evaluated.

12. The assembly as claimed in claim 1 wherein the electronic unit to be evaluated is a light-emitting means, particularly an LED module, an OLED module, a halogen lamp, a gas discharge lamp or a fluorescent lamp, an operating device for operating a light-emitting means or an operating device for actuating lamps or operating devices for light-emitting means.

13. A method for evaluating the state of an electronic unit used for illumination purposes, comprising:
a) detecting a plurality of physical parameters representing the current state of the electronic unit,
b) comparing the detected physical parameters after possibly mathematical evaluation or analysis alone or in combination with predetermined reference values or reference spaces (I, II),
c) on the basis of the comparisons, creating information describing the state of the electronic unit to be evaluated.

14. The method as claimed in claim 13, wherein during the creation of the state information, the comparison results are weighted to a different extent.

15. The method as claimed in claim 13, wherein the reference values or reference spaces (I, II) used for comparing are at least partially graded.

16. The method as claimed in claim 13 wherein the reference values or reference spaces used for comparing are specified during the production or immediately after production of the electronic unit to be evaluated, preferably on the basis of measurement results.

17. The method as claimed in claim 13 wherein the reference values or reference spaces (I, II) used for comparing remain permanently unchanged.

18. The method as claimed in claim 13 wherein the reference values or reference spaces (I, II) used for comparing are modified during the operating life of the electronic unit, wherein the modifying of the reference values or reference spaces (I, II) takes place preferably within a predetermined period of time after the electronic unit to be evaluated has been taken into operation.

19. The method as claimed in claim 13 wherein the detected physical parameters are, in particular, temperature, voltage, current, luminous flux, brightness, color, frequency, time values and/or spectral components.

20. The method as claimed in claim 13 wherein the electronic unit to be evaluated is a light-emitting means, particularly an LED module, an OLED module, a halogen lamp, a gas discharge lamp or a fluorescent lamp, an operating device for operating a light-emitting means or an operating device for actuating lamps or operating devices for light-emitting means.
